(19) United States
(12) Patent Application Publication
(10) Pub. No.: US 2006/0226903 A1
(43) Pub. Date: Oct. 12, 2006

(54) Method for signal processing and a transmitting device with digital predistortion, in particular for mobile radio

(76) Inventors: Jan-Erik Muller, Ottobrunn (DE); Nazim Ceylan, Munchen (DE)

Correspondence Address: ESCHWEILER & ASSOCIATES, LLC;NATIONAL CITY BANK BUILDING, 629 EUCLID AVE., SUITE 1210, CLEVELAND, OH, 44114, US

(21) Appl. No.: 11/388,698

(22) Filed: Mar. 24, 2006

(30) Foreign Application Priority Data
Mar. 24, 2005 (DE) DE 102005013881.0

(51) Int. Cl. H03F 1/26

(52) U.S. Cl. 330/149

(57) ABSTRACT

A transmitting device with digital predistortion is disclosed. The device produces a power word derived from an amplitude component of a digital modulation signal and a desired output power. The power word is compared with a limit value, and depending on the result, one pair of predistortion coefficients is selected and distortion of a first and second component of the digital modulation signal is thus carried out. The phase and the amplitude of a carrier signal are then modulated with the distorted components. Selective distortion of the modulation signal is carried out by comparison of the power word with a limit value, when the signal quality or the linearity of the modulated carrier signal falls below a predetermined limit value. Otherwise, the predistortion unit can be switched off, and the power consumption can thus be reduced.

### REFERENCE TO RELATED APPLICATIONS

This application claims the benefit of the priority date of German application DE 10 2005 013 881.0, filed on Mar. 24, 2005, the contents of which are herein incorporated by reference in their entirety.

### FIELD OF THE INVENTION

The invention relates to a method for signal processing, and to a transmitting device with digital predistortion, for example, for mobile radio.

### BACKGROUND OF THE INVENTION

The requirements of modern communication standards for the signal quality of transmitting devices and transceivers are becoming more stringent as the need for high data rates and increasing mobility grow. Mobile radio standards which have been used until now such as UMTS/WCDMA, GSM/EDGE, W-LAN or Bluetooth Medium Rate, use bandwidth-efficient modulation types for transmission of high data rates both from a base station to a mobile appliance and from a mobile appliance to a base station. Examples of these modulation types are QPSK (Quadrature Phase Shift Keying), 8-PSK (8-Phase Shift Keying) or QAM (Quadrature Amplitude Modulation). With these modulation types, both the phase and the amplitude of the so-called carrier signal are modulated in order to transmit the data.

The modulation types used are particularly sensitive to possible interference or distortion in the transmission path. Distortion is produced in the transmission path by various components. These lead to changes in the phase and the amplitude of the carrier signal, which thus has non-linear components with respect to an input signal that is used for modulation. In this context, it is also said that the output signal is not proportional to an input signal. The use of the stated modulation types is thus subject to stringent requirements for the linearity of the individual components in the transmission path, in order to keep distortion as low as possible. In this case, inter alia, this includes circuits within the transmission path whose characteristics have non-linear areas. The circuits have an at least partially non-linear transmission response. This includes in particular the individual amplifiers in the transmission path, which amplify the signal to be transmitted to the output power level. Particularly in the case of amplifiers, the transmission response is dependent on the amplitude of an input signal.

In the case of power amplifiers, high linearity is achieved by operating them considerably below their maximum achievable output power. However, operation of the power amplifier in this way leads to a high quiescent current consumption, thus increasing the power losses in the amplifier, and thus in the transmitting device. The increased power consumption in mobile communication appliances results in a decrease in the operating time, which is essentially predetermined by the capacity of the rechargeable batteries that are used.

In order to improve the efficiency, which is defined by the ratio of the output signal power produced to the battery power consumed, it is expedient to operate the power amplifiers on the transmitting device in the region of their maximum achievable output power. In this region, the power amplifiers have a very highly non-linear transmission response, however, so that the output signal is significantly distorted, and thus possibly leads to errors in data transmission.

In modern mobile communication appliances, a compromise is therefore desirable between the power consumption and the linearity of the individual components. This can be achieved by suitable circuitry. For example, the power consumption of the non-linear components can be reduced by choice of suitable biasing or of a suitable load impedance at their output. This method is described in the documents by G. L. Madonna et al.: “Investigations of Linearity Characteristics for Large Emitter Area GaAs HBT Power Stages”, GAAS 2001 Conference, London 2001 and Iwai et al.: “High Efficiency and High Linearity in GaP/GaAs HBT Power Amplifiers: Matching Techniques of Source and Load Impedance to Improve Phase Distortion and Linearity”, IEEE Transactions on Electronic Devices, Vol. 45, No. 6, June 1998. In order to improve the transmission response within the transmission path further, it is normal in modern transmitting devices to predistort the input signal.

With this type of improvement, a signal which is supplied to the amplifier and/or to the component with a non-linear transmission response is suitably distorted. The distortion is chosen so as to compensate for the distortion caused by the non-linear transmission response. A signal which is amplified with respect to and is proportional to an input signal can then be tapped off at the output of the amplifier or of the component with the non-linear transmission response.

Examples for predistortion within the analog signal processing chain are described in the documents Yamauchi et al.: “A Novel Series Diode Linearizer for Mobile Radio Power Amplifiers”, IEEEMTT-S 1996, pages 831-833 and E. Westesson et al.: “A Complex Polynomial Predistorted Chip in CMOS for Baseband or IF Linearization for RF Power Amplifiers”, IEEE International Symposium on Circuits and Systems 1999. Circuits for predistortion of analog signals can be produced at particularly low cost by means of simple additional elements. However, external operating conditions, some of which cannot be influenced, such as the temperature, the drive level of the components and operating points of the distorting circuit, can be changed only within narrow limits. Otherwise, additional readjustment of the predistortion circuit is required. Additional control circuits for predistortion of analog signals require additional space, increase the power consumption and lead to only moderate improvements in the linearity of the output signal.

In contrast to this, predistortion of a digital signal offers very good adaptability to changing external operating conditions. The predistortion is in this case carried out by variation of the digital baseband signals which are used in modern transmitters. In the case of so-called adaptive digital predistortion, a portion of the analog output signal is output downstream from the power amplifier, is demodulated and is converted back to a digital baseband signal. The distortion caused by the non-linear component within the transmission path, and in particular the distortion of the power amplifiers, can be determined from the comparison of the converted baseband signal with the originally undistorted baseband signal. The documents U.S. Pat. No. 6,477,477 and U.S. Pat. No. 4,291,277 disclose transmitting devices with adaptive digital predistortion.

### SUMMARY OF THE INVENTION

The following presents a simplified summary of the invention in order to provide a basic understanding of some aspects of the invention. This summary is not an extensive overview of the invention. It is intended neither to identify key or critical elements of the invention nor to delineate the scope of the invention. Rather, its primary purpose is merely to present one or more concepts of the invention in a simplified form as a prelude to the more detailed description that is presented later.

The invention is directed to a method for signal processing, which processes signals with little power consumption and produces a good signal quality. The invention also includes a transmitting device whose power consumption is less than that of conventional transmitters.

According to one embodiment, the method comprises providing at least one amplifier circuit in one operating state from a set of at least two operating states which are characterized by at least one characteristic variable, and providing a discrete-value and discrete-time modulation signal with a first component and with a second component. In addition, a carrier signal and a large number of selectable pairs of predistortion coefficients are provided. A power word is then produced which is derived from the first component of the modulation signal and a maximum value of the first component during a time period, and a comparison of the power word with a reference value is made, thereby producing a first or a second result.

A pair of predistortion coefficients are then selected from the large number of pairs of predistortion coefficients as a function of the first component and the control word. The first component is distorted with a first coefficient of the pair and the second component is distorted with a second coefficient of the pair when the comparison has produced the first result. The method further comprises modulating the phase of the carrier signal with the distorted second component of the modulation signal when the comparison has produced the first result, or modulating the phase of the carrier signal with the second component of the modulation signal when the comparison has produced the second result.

Further, the amplitude of the phase-modulated carrier signal is modulated as a function of the distorted first component of the modulation signal when the comparison has produced the first result, or modulated with the first component of the modulation signal when the comparison has produced the second result. The carrier signal is then amplified by the at least one amplifier circuit.

In one embodiment of the invention, a pair of predistortion coefficients is selected when necessary in order to obtain the linearity of the carrier signal that has been amplified by the amplifier circuit. This condition is evaluated by the comparison of the power word with the reference value. The power word, which is derived, inter alia, from the first component of the modulation signal, comprises information about the maximum amplitude which occurs in the modulation signal, and in particular, in the first component.

The power value, in one example, contains a maximum value of the first component. Since distortion resulting from the transmission response of non-linear components depends primarily on the input signal amplitude to the non-linear components, selective predistortion of the input signal is carried out via the evaluation of the amplitude of the input signal. Expressed in simple terms, in one example of the method, predistortion of the first and second components is carried out when the amplitude of a signal that is applied to the amplifier circuit is so high that a linear transmission response of the amplifier circuit is no longer ensured. The method can be used advantageously not only for amplifier circuits. In fact, it is suitable for all circuit elements which have a non-linear transmission response during operation.

In another embodiment of the invention, the power word contains information about a maximum of the first component occurring during a time interval. For this purpose, the power to be emitted during a time period of the carrier signal to be amplified is determined. In the same way, a maximum of the first component during this time period is determined. The power word is then produced from the determined power to be emitted and from the maximum of the first component during this time period. The comparison of the power word with the reference value can thus be used to make a decision as to whether the first and second component should or should not be predistorted with the predistortion coefficients during the time period.

A refinement of the method such as this is advantageous since, normally, the maximum power to be emitted and the maximum power that occurs during a time period are known. Consequently, predistortion is employed in one embodiment when the amplitude of the first component exceeds a limit value. Alternatively, another value of the first component can also be determined, for example, an average power or a crest factor.

In another embodiment of the invention the method comprises recording a characteristic variable of the at least one amplifier circuit and producing a selection word from the recorded characteristic variable. The characteristic variable can advantageously be used to select a pair of predistortion coefficients from the large number of pairs of predistortion coefficients on the basis of the recorded characteristic variable.

Another embodiment of the invention relates to the pair of predistortion coefficients with which predistortion is carried out. This may be dependent on the first component, the power word and the selection word. In this embodiment, it is expedient for the recording of the at least one characteristic variable to comprise at least one of: determining a temperature of the at least one amplifier circuit; determining a current consumption of the at least one amplifier circuit; determining a supply voltage of the at least one amplifier circuit; determining an impedance or an impedance change of the at least one amplifier circuit; determining a reflection coefficient at a signal output of the at least one amplifier circuit; or determining a phase and/or an amplitude of an output signal from the at least one amplifier circuit.

During operation of a transmitting device, the transmission response of an amplifier circuit or of a non-linear component can change due to external operating conditions, such as a temperature, a power consumption, a supply voltage or an impedance. The recording of at least one characteristic variable according to one embodiment of the invention therefore makes it possible to identify even dynamic effects during operation, and to appropriately change the predistortion coefficients. The method is thus even suitable for changes in external operating conditions.

In one embodiment of the invention, the at least one operating variable is determined by outputting a signal element from the amplified carrier signal that is emitted from the at least one amplifier circuit, and converting the signal element using a local-oscillator signal. The frequency-converted signal element is then decomposed into a third and a fourth component, from which the selection word is produced.

In another embodiment of the invention, a discrete-value or discrete-time modulation signal is produced with an in phase component as well as a quadrature component, and the first component is produced by forming the square of the magnitude from the in-phase component and the quadrature component. The first component forms an amplitude element from the in-phase component as well as the quadrature component. The second component is produced from the in-phase component and the quadrature component, and forms phase information about the modulation signal. In other words, the in-phase component and the quadrature component of the discrete-value and discrete-time modulation signal are transformed to an amplitude element and a phase element.

This feature is advantageous since the amplitude element of the discrete-value and discrete-time modulation signal is essentially responsible for the distortion within the non-linear components. Furthermore, the amplitude element as well as the phase element can be used respectively as the first component and the second component directly for predistortion in contrast to an in-phase component and a quadrature component. It is thus possible in accordance with one embodiment of the invention to carry out selective predistortion of the discrete-value and discrete-time modulation signal by evaluation of the power word, which in one example includes the information about the maximum amplitude element of the discrete-value and discrete-time modulation signal.

A decision is accordingly made in the comparison act as to whether the amplitude of the first component is greater than or less than a limit or reference value. The first or the second result is produced as a function of the comparison.

In one embodiment of the invention, the large number of pairs of predistortion coefficients are arranged. Each pair of predistortion coefficients can be associated with an address. An address is then formed from the first component and the power word by multiplying or scaling the first component by a factor which is derived from the power word. The result is used to determine the address and the associated pair.

One embodiment of the invention relates to the arrangement of the large number of pairs of predistortion coefficients in a first table element and in at least one second table element. An address can be allocated to each of the pairs. In this example, it is advantageous for the address which can be allocated to each pair to have a first address part and a second address part. The first address part is the same for the pairs of distortion coefficients which are associated with the same table element. A pair is advantageously chosen by addressing, with the first address part being derived from the selection value, and the second address part being formed from the control signal and the first component.

This feature facilitates accounting for changing operating conditions. The various table elements contain pairs of predistortion coefficients, which are then selected as a function of the power word and of the first component. If the external operating conditions change, then the selection word also changes, and a new table element is selected.

In another embodiment of the invention, the selection of one pair from the large number of pairs of predistortion coefficients comprises the formation of a new pair from the first and the second component, the control word, the selection word, and the determined pair of predistortion coefficients. The determined pair of predistortion coefficients is then replaced by the newly formed pair of predistortion coefficients. In this embodiment, there is no need to provide a plurality of table elements in order to take account of the different external operating conditions. If the external operating conditions change, a new pair of predistortion coefficients is formed, which account for the external operating conditions by means of the selection word.

This embodiment of the invention also makes it possible to make the formation of new pairs of predistortion coefficients dependent on further parameters. In one refinement, the chronological age of the pairs of predistortion coefficients or their last change is used to decide whether a new pair should be formed.

In another embodiment of the invention, a transmitting device, in particular for mobile radio is disclosed, comprises a signal processing device which is designed to produce a discrete-value and discrete-time modulation signal and to emit the modulation signal with a first component and a second component. Furthermore, the signal processing device is designed to emit a power control signal which is derived from the first component. A predistortion device is coupled to the signal processing device and contains a first signal path, which couples the input connections of the predistortion device to its output taps.

A second signal path which is likewise provided comprises switching elements for distortion of signals which are applied to the first and the second connection, as a function of a signal which is applied to a control input of the predistortion device, and a signal which is present at the first connection. This connection can be supplied with the first component of the modulation signal which is emitted from the signal processing device and, in one example, includes the amplitude information of the discrete-value and discrete-time modulation signal.

In one embodiment, the predistortion device is designed to assume one operating state from a set of two available operating states. The first signal path is active in the first operating state, and the second signal path is active in the second operating state. In other words, the predistortion device is designed to connect its input connections to its output taps in the first operating state, and to distort signals that are applied to its input side in the second operating state, as a function of the signal which is applied to the control input and the signal which is present at the first connection.

In another embodiment, on the output side, a modulation unit is provided, which is connected to a second output tap of the predistortion device and is designed to modulate the phase of a carrier signal with a signal that is applied to its input. A variable-gain amplifier circuit is coupled to the output of the modulation unit. Finally, a power control unit is provided, whose input side is coupled to the control output of the signal processing device. The power control unit has a first output and a second output. The first output is connected to the control input of the predistortion device. The second output is coupled to the amplifier circuit, for gain adjustment. The power control unit is designed to emit a control signal (at the first output) for predistortion and to emit a gain adjustment signal at the second output, derived from the power control signal at its input.

The transmitting device according to one embodiment of the invention is used to control predistortion of a modulation signal with a first and a second component as a function of a power control unit. For this purpose, the predistortion device is designed to bridge predistortion in one operating state and emit the components of the modulation signal that are applied to its input side, without distortion. In this operating state, the switching elements which are required for predistortion can be switched off, thus reducing the power consumption of the transmitting device.

According to one embodiment of the invention, predistortion is carried out in a second operating state of the predistortion device, and is adjusted by the control signal, which is emitted from the power control unit, at the control input of the predistortion device. In this example, the signal processing device emits a first component, which forms the amplitude element of the modulation signal, and a second component, which forms the phase element of the discrete-value and discrete-time modulation signal. This allows predistortion to be carried out particularly easily.

In another embodiment of the invention, means are provided for recording a characteristic variable of the amplifier circuit. The characteristic variable describes an instantaneous operating state of the at least one amplifier circuit. The means are designed to produce and emit a control word to the predistortion device. If the distortion in the second signal path of the predistortion device changes, the selection word which is produced by the means changes as a function thereof. In this embodiment, the predistortion device and, in particular, the second signal path of the predistortion device are designed to produce distortion as a function of the selection word. Thus further characteristic variables which can vary with time may be recorded and taken into account appropriately in the predistortion of the signal.

In one embodiment of the invention, the means can represent a temperature sensor, for recording a temperature of the amplifier circuit, in a suitable manner. In another embodiment, the means can likewise form a detector for recording the power consumption of the amplifier circuit, or a voltage measurement device for recording a supply circuit for the amplifier device. In another embodiment, a detector is provided in order to determine reflection coefficients at a signal output of the amplifier circuit. In one embodiment, the amplifier circuit is designed with a detector in order to measure an impedance or an impedance change. In another embodiment, the output of the amplifier circuit is coupled to a detector for recording an amplitude and a phase of an output signal from the amplifier circuit.

The detectors can also be combined, in one example, in order to obtain a more accurate statement about the instantaneous operating state of the at least one amplifier circuit. Dynamic effects can be determined from the various characteristic variables, and can be used to produce a selection value. This may be used to determine predistortion of the first and second component of the discrete-value and discrete-time modulation signal.

In another embodiment of the invention, the predistortion device comprises a memory having a large number of addressable pairs of predistortion coefficients stored therein. An address unit is connected to the memory and is designed to produce an address of a pair of predistortion coefficients apart from the first component and the signal which is applied to the control input. The addressing of a pair with the aid of the address unit as a function of the first component and the signal which is applied to the control input makes it possible to select one pair of predistortion coefficients. In one embodiment of the invention, the address unit is designed to multiply the first component by a factor which is derived from the signal which is applied to the control input. This makes it possible to scale the first component. This is particularly advantageous when the first component covers the completely available digital range.

A further embodiment of the invention includes a refinement of the predistortion unit. This may comprise a calculation unit which is designed to calculate a new pair of predistortion coefficients from the first component, the selection word and a pair of predistortion coefficients determined from an address that is produced. The calculation unit is also connected to the memory, in order to store the new pair in the memory, at the address that is produced.

The calculation unit allows the size of the memory to be reduced, since changes to the external operating conditions and changes in the at least one amplifier circuit can be taken into account by calculation of a new pair of predistortion coefficients. The calculation unit can also be operated selectively, so that the pairs of predistortion coefficients are updated only when or if necessary because of changes in the operating conditions. In yet another embodiment of the invention, a multiplication unit is arranged in the second signal path of the predistortion device between the first connection and the first output tap. This multiplication unit is designed to multiply the first component, which represents an amplitude element of the discrete-value and discrete-time modulation signal, by a first coefficient of a pair of predistortion coefficients. An addition unit is likewise provided in the second signal path between the second connection and the second output tap. The addition unit is designed to add the second component, which represents a phase element, to a second coefficient. The first and the second components are distorted with their appropriate coefficients by the multiplication unit and the addition unit. The two coefficients form the pair of predistortion coefficients.

In another embodiment, the amplifier circuit comprises a modulation input for supplying a modulation signal in order to vary the gain of the amplifier circuit. The modulation input of the amplifier circuit is coupled to the first output tap of the predistortion device. The first component, which is emitted from the predistortion device at the first output tap, can be used to adjust the gain in the amplifier circuit, and thus achieve amplitude modulation of a signal which is applied to the input of the amplifier circuit.

To the accomplishment of the foregoing and related ends, the invention comprises the features hereinafter fully described and particularly pointed out in the claims. The following description and the annexed drawings set forth in detail certain illustrative aspects and implementations of the invention. These are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

The invention will be explained in detail in the following text using a plurality of exemplary embodiments and with reference to the drawings, in which:

FIG. 1 is a combined block/schematic diagram illustrating an exemplary embodiment of a transmitting device according to the invention,

FIG. 2 is a combined block/schematic diagram illustrating an exemplary embodiment of a transmitting device according to the invention,

FIG. 3 is a schematic diagram illustrating an exemplary embodiment of a predistortion unit according to the invention,

FIG. 4 illustrates one example of an addressing unit which is part of the predistortion unit,

FIG. 5 is a block diagram illustrating an exemplary embodiment of a phase modulator,

FIG. 6 is a combined block/schematic diagram illustrating an embodiment of a supply circuit for a power amplifier,

FIG. 7 is a combined block/schematic diagram illustrating another embodiment of a transmitting device according to the invention,

FIG. 8 is a combined block/schematic diagram illustrating yet another embodiment of a transmitting device according to the invention,

FIG. 9 is a combined block/schematic diagram illustrating still another embodiment of a transmitting device according to the invention,

FIG. 10 is a combined block/schematic diagram illustrating another embodiment of a transmitting device according to the invention,

FIG. 11 is a schematic diagram illustrating another embodiment of a predistortion unit in a transmitting device,

FIG. 12 is a combined block/schematic diagram illustrating an embodiment of a detector for recording an operating variable,

FIG. 13 is a flow chart illustrating an exemplary embodiment of a method according to the invention,

FIG. 14 is a flow chart illustrating another exemplary embodiment of the method according to the invention,

FIG. 15 is a flow chart illustrating yet another embodiment relating to the selection of a pair of predistortion coefficients according to one embodiment of the invention,

FIG. 16 is a flow chart illustrating still another exemplary embodiment of the method according to the invention.

### DETAILED DESCRIPTION OF THE INVENTION

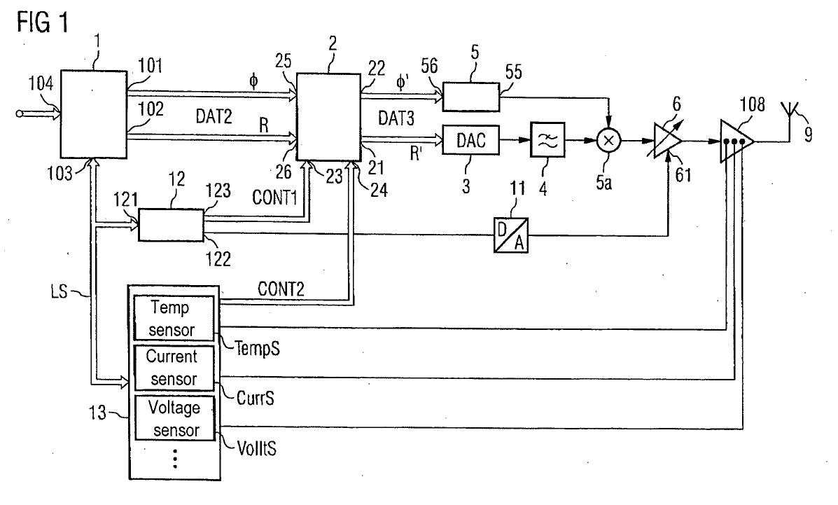

FIG. 1 shows one embodiment of a transmitting device with a predistortion unit which is designed according to one embodiment of the invention. The transmitting device, in one example, is based not carrying out continuous predistortion of a signal to be transmitted. Instead, predistortion of the so-called digital baseband signal is carried out selectively; that is, whenever the requirements for the linearity of the signal to be emitted from the transmitting device can no longer be complied with an undistorted baseband signal.

Non-linear signal components in the signals to be emitted result from circuits and/or components which have a non-linear area in at least a part of their characteristic being provided in the transmission path of the transmitting device. If the drive level and the amplitude at the circuits and the input signals applied to the components lead to the circuits and/or components being operated in the non-linear ranges, then the output signal contains additional non-linear components with respect to the input signal. This is also referred to as the output signal not being proportional to the input signal. So-called non-linear transmission of the input signal via the circuits or the components leads to distortion and interference in the output signal, which can cause data transmission errors.

In order to correct these non-linearities in the output signal caused by the circuit elements, the digital baseband signal is thus suitably predistorted before being supplied to the circuit elements or components with areas in which their transmission response is not linear. Since, as already mentioned above, non-linearity in the output signal is highly dependent on the amplitude of the input signal, it is expedient to have available relatively detailed information about the instantaneous amplitude of the input signal. This allows predistortion to be selectively switched on and off depending on whether the amplitude reaches a limit value at which predistortion is necessary.

Since the digital baseband signal is not predistorted continuously but only at times, this makes it possible to reduce the average power consumption of a correspondingly designed predistortion circuit. Nevertheless, good signal quality is still ensured. Furthermore it is still possible to operate the circuit and components arranged downstream from a predistortion device with high efficiency, that is to say with a high ratio of the output power to the input power.

FIG. 1 shows a transmitting device which operates using this principle according to one exemplary embodiment of the invention. For this purpose, the transmitting device contains a baseband unit 1 with an input 104 to which the data to be transmitted is applied. The baseband unit 1 uses this to produce a digital data stream comprising a large number of bits. Depending on the chosen type of modulation, a number of bits are combined to form a so-called symbol. In the case of the QPSK modulation type, two bits in each case form one symbol. In this context, the QPSK modulation type is also referred to as a two-value modulation type. In a corresponding manner, three bits are in each case combined to form one symbol in the 8-PSK modulation type. Some of the various embodiments of quadrature amplitude modulation (QAM) combine four or more bits to form one symbol in each case.

An unambiguous phase and an amplitude are associated with each of the combined symbols. The baseband unit 1 knows the maximum amplitude of the signal to be transmitted during a time period. From the knowledge of the maximum amplitude together with the knowledge of the desired output power of the transmitted signal from the transmitting device, the baseband unit calculates a power word LS and emits this at its output 103.

The amplitude element R is emitted concurrently as a first discrete-value and discrete-time component at a first output tap 102. The corresponding phase information Φ is emitted at a second output tap 101, as a second discrete-value component. The first component R and the second component Φ form the discrete-value and discrete-time modulation signal DAT2. This is supplied to the inputs 25 and 26 of the predistortion unit 2. The predistortion unit also contains a first control input 23 and a selection input 24. The respective control signal CONT1 or CONT2 can be supplied to its inputs 23 and 24, controlling the response of the predistortion unit 2.

FIG. 3 shows one example of the predistortion unit 2 as shown in the exemplary embodiment in FIG. 1. Components which have the same effect and/or the same function are annotated with the same reference symbols. The predistortion unit 2 contains a switching apparatus 27, whose input side is connected to the input connections 25 for the second component Φ and 26 for the first component R. The predistortion unit 2 also contains a first and a second signal path. Both signal paths are connected on the input side to the outputs of the switching apparatus 27. The first signal path couples the outputs of the switching apparatus 27 directly to the respective outputs 21 and 22 of the predistortion device 2. The input connections 25, 26 in the first signal path are thus connected directly to the output taps 21 and 22.

The second signal path in each case contains a delay element 28. In addition, it has a multiplier 141 in the path element of the second signal path for the first component R which is designed to multiply the component R applied to its input side by a coefficient MAG_COEFF. The output of the multiplier 141 is connected to the output 21 for the first component R′.

An adder 142 is arranged in the second path element for the second component Φ between the output of the switching apparatus 27 and the delay element 28. This adder 142 adds the second component Φ to a coefficient PH_COEFF, and emits the result at the output 22 of the predistortion unit 2. In summary, the second signal path has elements which apply the discrete-value and discrete-time modulation signal DAT2 to the amplitude element R and to the phase element Φ with corresponding predistortion coefficients MAG_COEFF and PH_COEFF, thus carrying out predistortion. The components, denoted R′ and Φ in the following text, are emitted at the output taps 21 and 22.

The switching apparatus 27 has a control input 271. Depending on a control signal at the control input 271, it connects the inputs 25 and 26 to the output taps 21 and 22, or the inputs 25 and 26 to the adder 142 and to the multiplier 141, respectively.

The control input 271 of the switching apparatus 27 is connected to the control input 23 for the first control signal CONT1. The predistortion device 2 is controlled by the control signal CONT1 in such a way that it either emits components R and Φ applied to its input side without distortion at its output, or applies coefficients to them and predistorts them. In the first case, the further components 28, 141, 142 and 17, which in particular are intended for predistortion purposes can thus be switched off so that the power consumption of the overall predistortion device 2 is reduced.

If, in contrast, the control signal CONT1 at the control input 23 is switched by the switching apparatus 27 such that the second signal path is active and the two components R and Φ are supplied to the second signal path for predistortion, it is necessary at the same time to select the suitable predistortion coefficients. As already mentioned, these depend on the instantaneous signal amplitude of the first component R applied to the input side. For this purpose, the first component R is supplied to a device 17.

The device 17 has a memory in which various coefficient pairs COEFF1 are stored. The coefficient pairs COEFF1 are in this case arranged in tabular form. In the present exemplary embodiment the memory 15 contains two different table elements 15a and 15b. One of the two table elements 15a or 15b can in each case be selected by a second control or selection signal CONT2 at a selection input 24.

As will be explained later, the selection signal makes it possible to take account of various external operating conditions. The pairs of predistortion coefficients in the table elements are matched to the operating conditions.

Each of the two table elements 15a and 15b contains a plurality of pairs of predistortion coefficients COEFF1. Each pair of predistortion coefficients contains some of the coefficients for the amplitude MAG_COEFF and some of the coefficients for the phase PH_COEFF. The individual pairs of predistortion coefficients are determined by selection of an address and are emitted from memory 15 to the multiplication unit 141 or the addition unit 142.

The address is transmitted via an address word ADR to the memory. An addressing unit 16 is provided for this purpose and uses the first component R at the input 161 and the control signal CONT1 at the control input 23 to produce an address word ADR which it emits at the output 162. The address value is used for selection of the pair of predistortion coefficients from the table element 15a or 15b, which is used as a function of the control signal CONT2.

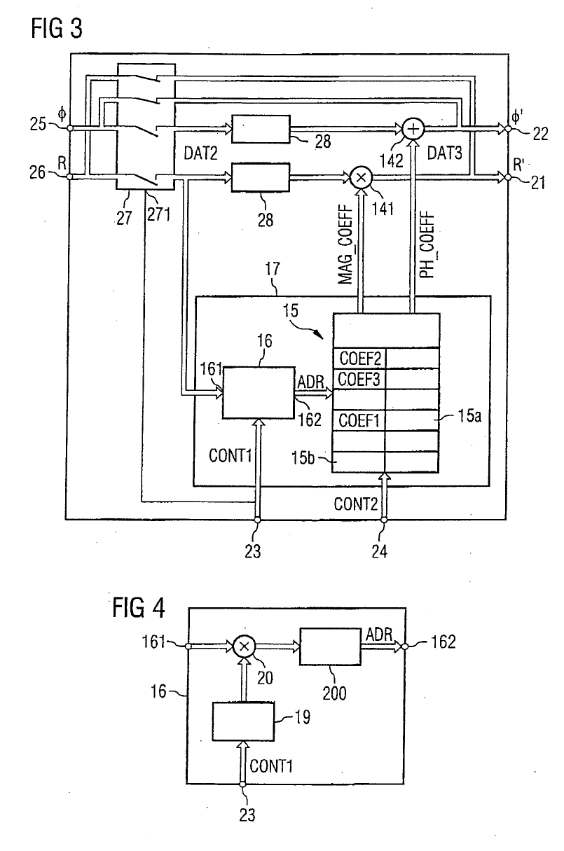

FIG. 4 shows another example of an address unit 16 in accordance with the invention. The address unit 16 has a multiplier 20 as well as a factorizer 19. The input side of the multiplier 20 is connected to the output of the factorizer 19 and to the input 161 for supplying the first component R. The output of the multiplier 20 is connected to a quantizer 200 which uses the result of the multiplication by the multiplier 20 to calculate the address word ADR, which is emitted at the output 162 of the address unit 16.

The supply of the control signal CONT1 and the multiplication of the first component R by a factor which is derived from the control signal CONT1 lead to scaling of the first component R. The control signal CONT1 contains the information about the maximum amplitude in the first component R during a specific time period and the desired output power. This amplitude is used to decide whether the first or the second transmission path from the predistortion device 2 is active. When predistortion is carried out, this does not necessarily mean that the value of the first component R contained in the control signal CONT1 must be used for all of the predistortion coefficients.

Since the table element within the memory 15 includes all of the pairs of predistortion coefficients for all of the values of the first component R that arise, it is advantageous in one embodiment to select only those components required during the time period that is predetermined by the control signal CONT1. The scaling of the first component R with the signal CONT1 and the subsequent address formulation are thus used to select only one area from the corresponding table element, and to determine the address from there.

In one example, the power control signal CONT1 indicates that, during a predetermined time period, the maximum value of the first component R during this time period corresponds to approximately 80% of the maximum possible output power of the transmission signal. This means that the downstream circuit elements with their non-linear transmission responses are operated approximately only in an 80% region of their characteristic. The remaining 20% is not reached. In consequence, the predistortion coefficients in the respective table element are also not required for the remaining 20%. Consequently, the first component R is scaled by a factor of 0.8 in order to determine the address value. If, for example the first component can assume a total of 256 different values, the scaling process results in the selection of only the first 256*0.8=204 coefficient pairs, rather than all of the 256 coefficient pairs from the corresponding table element.

The drive level of the component R in the baseband unit is thus taken into account by the control signal CONT1 and the corresponding scaling by the device 19 and the multiplication unit 20.

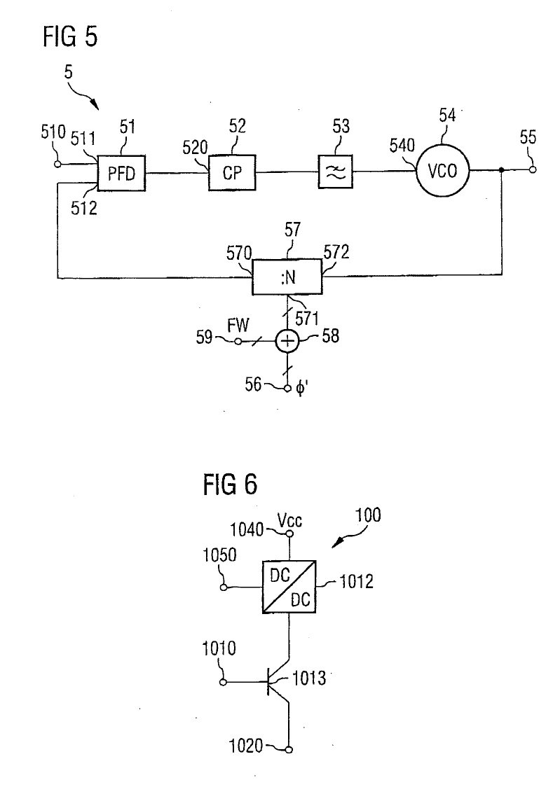

The first component R′ and the second component Φ′ at the outputs 21 and 22 form the discrete-value and discrete-time modulation signal DAT3. This is used to modulate a carrier signal, as illustrated by way of example in FIG. 1. For this purpose, the second component Φ′ of the discrete-value and discrete-time modulation signal DAT3 at the output 22 of the predistortion unit 22 is supplied to the input 56 of a phase modulator 5. FIG. 5 shows one example of a phase modulator.

The example phase modulator of FIG. 5 has a control loop formed from a phase detector 51, a charge pump 52, a downstream filter 53, and a voltage controlled oscillator 54. The phase detector 51 compares the phases of two signals which are applied to the inputs 511 and 512 and uses this comparison to produce a control signal, which is supplied via the charge pump 52 and the loop filter 53 as a control signal, to the control input 540 of the voltage controlled oscillator 54. The frequency of the output signal from the oscillator 54 is varied as a function of the control signal. On the output side, a voltage controlled oscillator 54 is connected to the output of the phase modulator 55.

The phase modulator 5 also contains a feedback path with a frequency divider 57 which, in the present example is in the form of a Σ-Δ frequency divider (sigma-delta frequency divider). The division ratio of the frequency divider 57 can be adjusted by means of a corresponding control signal at the control input 571. On the output side, the frequency divider 57 is connected to the input 512 of the phase detector 51. A signal at a reference frequency can be supplied to the first input 511 of the phase detector 51. The control input 571 of the frequency divider 57 is connected to the output of an adder 58. The adder 58 adds a frequency adjustment word FW at the input 59 to the second component Φ′ at the input 56. The frequency adjustment word FW is used to set a carrier frequency for the output signal for the phase modulator.

The second component Φ′ forms the phase component or phase modulation. The result is supplied from the adder 58 to the frequency divider 57, whose division ratio is controlled on the basis of the sum of the frequency adjustment word FW and the second component Φ′. Any change in the frequency division ratio as a result of the phase modulation by the second component Φ′ results in a phase change or frequency change in the output 55 of the phase modulator 5. The second component is used to produce phase modulation on a carrier signal.

Referring again to FIG. 1, the first component R′, which forms the amplitude component of the discrete-value and discrete-time modulation signal DAT3, is supplied at the input of a digital/analog converter 3. The output of the digital/analog converter 3 is connected via a low-pass filter 4 to one input of a mixer 5a. The local oscillator input of the mixer 5a is connected to the output 55 of the phase modulator 5. Owing to possible predistortion of the amplitude component R it is advantageous in one example to take account of the fact that the resolution of the digital/analog converter 3 should be chosen to be one or more bits higher when predistortion of the amplitude component changes by a factor of 2, 4 or 8.

The digital/analog conversion of the first component R′ results in an amplitude-modulated signal being supplied to the input of the mixer 5a, which converts its frequency with the phase modulated signal. A phase-modulated and amplitude-modulated carrier signal can thus be tapped off at the output of the mixer 5a. The output of the mixer 5a is connected to the input of a variable-gain amplifier 6. On the output side, the controllable amplifier 6 is connected to the input of a power amplifier 108. The output of the power amplifier 108 is connected to the antenna 9. Large parts of the transmission characteristic of the power amplifier 108 have a non-linear profile. In consequence, the output signal is distorted primarily by the processing by the power amplifier 108. The power amplifier 108 thus, in one example, contains a plurality of sensors which determine various operating parameters and characteristic variables of the amplifier.

A characteristic variable is a value which is characteristic of the amplifier and allows conclusions to be drawn about the transmission response, and hence about the intensity and the nature of the distortion by the power amplifier 108. Characteristic variables such as these are, for example, the temperature, a current drawn, a supply voltage, an input and/or output impedance or a varying reflection coefficient. A characteristic of the power amplifier, and thus the gain of the output signal, vary as a function of these external conditions, some of which may not be predicted or controlled. This leads to distortion. Accordingly, in order to compensate for the distortion by means of suitable predistortion of the digital baseband signal and, in particular, the discrete-value and discrete-time modulation signal DAT1, it is advantageous in one embodiment of the invention to accurately record as many characteristic variables as possible, in order to obtain the instantaneous operating state of the amplifier circuit. In the present exemplary embodiment, a plurality of sensors are provided for this purpose, and are combined to form a unit 13.

The unit 13 uses the values from the individual sensors to calculate and produce a selection signal CONT2, and supplies this to the control input 24 of the predistortion device 2. The predistortion signal CONT2 is used to select one of various table elements in the predistortion device 2, which each take account of the different external operating conditions. In one exemplary embodiment, the influence of the temperature, as well as a power consumption or a current drawn, for example can be determined by the two sensors TempS and CurrS, and can be used to generate a selection signal CONT2. This selects one of the total elements, depending on the temperature and the power consumption. In the illustration of the transmitting device shown in FIG. 1, all that are determined are various characteristic variables for the power amplifier 108. However, it is also possible to also use suitable sensors to evaluate the further relevant components which produce non-linear signal components and such alternatives are contemplated as falling within the scope of the invention.

In addition to the selection of the correct table elements from the plurality of table elements by means of the selection signal CONT2, the selection signal CONT1 can also be supplied to the control input 23 of the predistortion device 2. This selection signal is used to determine whether the components Φ and R (applied to the input side) of the discrete-value and discrete-time modulation signal DAT2 should be distorted. A power control unit 12 is provided for this purpose, whose first output 123 is connected to the input 23 of the predistortion device 2. On the input side, the power control unit 12 is connected in order to supply the power control signal LS from the baseband unit. The power control unit 12 uses the power control signal LS to determine the desired output power for the signal to be emitted via the antenna 9. The power control unit 12 in this case knows the gain factor of the power amplifier 108. The necessary average amplitude of the input signal for the amplifier 108 can be determined from this. The power control unit 12 uses this value to decide whether it is necessary to predistort the first and the second components of the discrete-value and discrete-time modulation signal DAT2.

From this, it produces the power control signal CONT1, which it emits at its output 123. At the same time, it sets the gain of the controllable amplifier 6 by means of a signal at its output 122. The digital/analog converter 11 which is connected between the output 122 of the power control unit 12 and the control input 61 is used to convert the digital adjustment signal to a corresponding analog adjustment signal. If a digitally controllable amplifier is provided instead of the voltage control amplifier 6 described here, there is no need for the digital/analog converter 11.

Together with the digital/analog converter 3, the low-pass filter 4 and the mixer 5a, the phase modulator 5 described here forms a polar modulator. It is also possible to use an IQ modulator, instead of the polar modulator as described here.

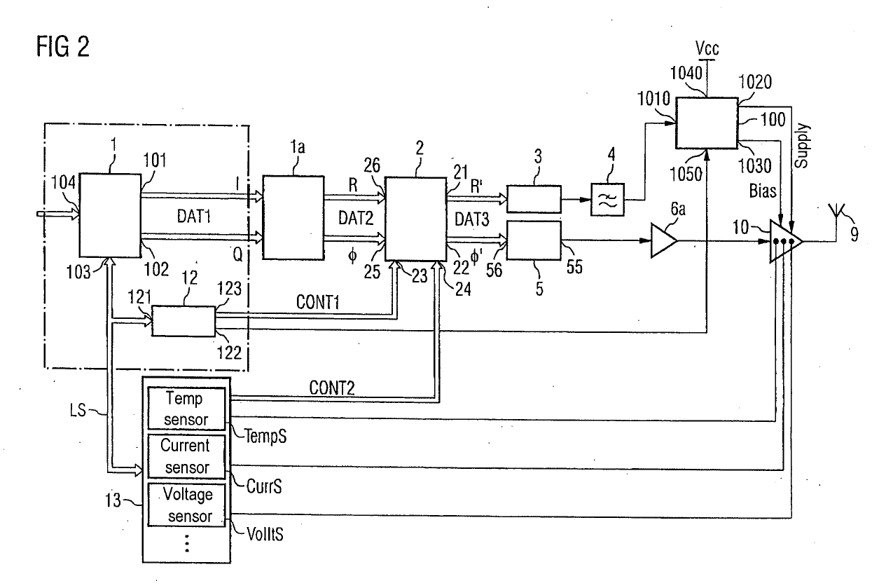

A transmitting device in accordance with another embodiment and having a polar transmitter is shown in FIG. 2. Components which have the same effect and/or function are provided in this case with the same reference symbols. In the present exemplary embodiment, the baseband unit 1 and the power control unit 12 are in the form of integrated circuits in a semiconductor body. This is indicated by the dashed-line boundary around the baseband unit 1 and the power control unit 12. In this case, the baseband unit 1 is designed to emit a discrete-value and discrete-time modulation signal DAT1, which comprises an in-phase component I and a quadrature component Q.

The in-phase component I and the quadrature component Q are converted by a converter 1a to an amplitude component R and a phase component Φ. The amplitude component R forms the first component, and the phase component Φ the second component of the discrete-value and discrete-time modulation signal DAT2.

This embodiment makes it possible to calculate an amplitude component and a phase component largely independently of the output signals in the baseband unit. The transmitting device can thus be produced using existing elements, without a high degree of additional complexity. On the output side, the circuit 1a is connected to the inputs 25 and 26 of the predistortion unit 2. This predistortion unit 2 is designed in the same way as the predistortion unit 2 in the embodiment shown in FIG. 1 in this example. It also contains a memory in which a plurality of table elements with pairs of predistortion coefficients are stored.

The output 22 of the predistortion unit 2 is once again connected to the phase modulator 5. The output 21 for the amplitude component is connected to the digital/analog converter 3. In contrast to the polar modulator illustrated in FIG. 1, no additional mixer is in this case provided for modulation of the amplitude components onto the phase-modulated carrier signal. In fact, the transmitting device has a supply control circuit 100, which is designed with a first control input 1010 for supplying the first component and the amplitude component R′ of the modulation signal DAT3 to the output of the low-pass filter 4. A further control input 1050 is coupled to the output 122 of the power control unit 12.

The supply control circuit 100 uses the two control signals that are applied to the inputs 1010 and 1050 and a supply voltage VCC at the input 1040 to produce a bias voltage at the output 1030, as well as a supply voltage at the output 1020. These are supplied to the power amplifier 10. The gain in the power amplifier is amplitude-modulated by controlling the bias voltage and/or the supply voltage for the power amplifier 10, thus varying the amplitude of the phase-modulated carrier signal. The combination of the phase modulator 5, the power amplifier 10 and the voltage supply control circuit 101 is referred to as a polar transmitter.

If desired, as illustrated here, an amplifier circuit 6A is connected between the output 55 of the phase modulator 5 and the input of the power amplifier 10. The modulation of the supply voltage for the amplifier 10 on the one hand with the amplitude component R and with a corresponding control signal emitted by the power control unit 12 leads to modulation of the gain in the power amplifier 10.

FIG. 6 shows one simple example embodiment of the supply voltage control circuit 100, which comprises a DC/DC voltage converter 1012 with a control input which is connected to the input 1050. The DC/DC voltage converter, which is also referred to as a DC/DC or switched-mode regulator, uses a DC voltage Vcc at the input 1040 to produce a second DC voltage, and emits this at its output. The DC voltage that is produced may in this case be greater than or less than the input voltage Vcc, depending on the embodiment of the DC/DC voltage converter 1012. For amplitude modulation of the phase-modulated carrier signal, a series regulator 1013 is arranged between the output of the DC/DC voltage converter 1012 and the output 1020 of the supply voltage control circuit 100. In the present exemplary embodiment, the series regulator 1013 is in the form of a bipolar transistor, whose control connection forms the input 1010. The change in the conductivity of the bipolar transistor leads to a voltage drop across the series regulator 1013, and thus to different voltages at the output 1020.

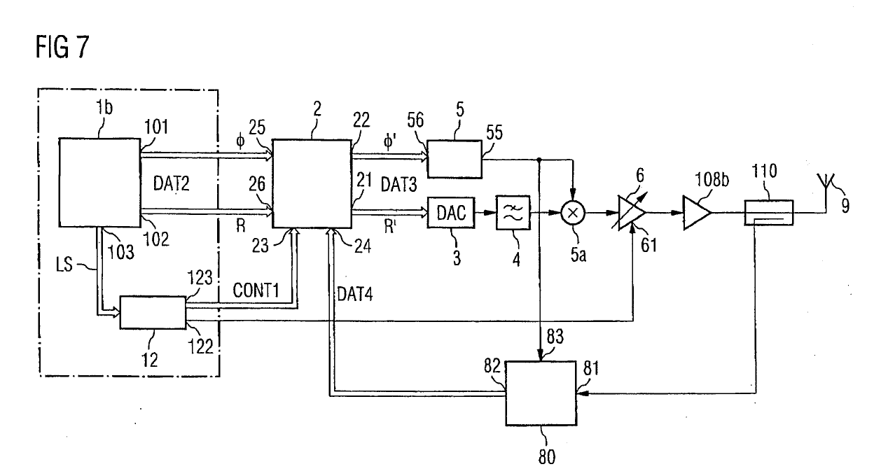

A further embodiment of the transmitting device is shown in FIG. 7. Components which have the same effect and/or the same function are in this case once again provided with the same reference symbols. As already explained with reference to the embodiment of the transmitting device shown in FIGS. 1 and 2, it is desirable to determine the operating values as accurately as possible in order to determine any distortion caused by circuits with a non-linear transmission response. In the embodiment shown in FIG. 7, this is achieved by feeding back and evaluating the signal which is emitted from the power amplifier 108B. In this case, use is made of the fact that, at least in some cases, different operating conditions result in the same distortion. It is thus possible by evaluating the signal emitted from the amplifier 108B to determine this distortion, and to take account of it in a suitable form. There is no longer any need to record the characteristic variables in order to determine an operating state.

The baseband unit 1b which, together with the power control unit 12, is in the form of an integrated circuit in a semiconductor body, is once again connected on the output side to the predistortion unit 2. In the present case, however, a directional coupler 110 is provided between the output of the power amplifier 108B and the antenna 9 and outputs a portion of the transmission signal, which it supplies in a feedback path to a circuit 80. The circuit 80 uses this to determine an amplitude as well as a phase of the fed-back signal, and produces a power control signal DAT4 at its output 82. The output 82 is once again connected to the input 24 of the predistortion device 2 in order to select one table element from a large number of tables. The information about the amplitude and any possible phase difference is required in order to produce the power control signal DAT4. For this purpose, the input 83 of the circuit 80 is coupled to the output 55 of the phase modulator 5.

One possible embodiment of the circuit 80 is shown in FIG. 12. In order to determine the amplitude component, a first signal path is provided which contains, inter alia, an envelope detector 804, which has a diode connected in the signal path and a capacitance connected to the output of the diode. The circuit 804 determines the envelope of the output signal and then amplifies this in the amplifier 805. The output of the amplifier is connected to an analog/digital converter 806, which uses the envelope to produce a digital signal which essentially indicates the instantaneous amplitude of the envelopes. The second signal path in the circuit 80 is used to determine any phase difference between the output signal and the phase-modulated carrier signal. In this case, it should be noted that delay time differences between the signals likewise lead to phase differences. Delay elements that are not described in any more detail are thus provided in order to compensate for the possible delay time difference.

The input 81 of the circuit 80 is connected to a limiting amplifier 800, whose output side is connected to a multiplier 801. The second input of the multiplier 801 leads to the control input 83 for supplying the phase-modulated carrier signal.

The multiplication unit 801 forms the difference between the signals applied to its input side. The output signal from the multiplication unit 801 is accordingly a DC voltage or an AC voltage at a very low frequency, which represents a measure of the phase shift or the distortion of the output signal. The output signal from the multiplication unit 801 is supplied via a low-pass filter 802 to a voltage detector 803. If a suitable choice is made, the voltage detector 803 can also be omitted. The signal is then converted to a digital value, and is supplied together with the amplitude information to the device 807, which uses it to produce the control signal DAT4, which it emits at its output 82.

The transmitting device described here is suitable not only for time-slot-based data transmission methods, but also for data transmission methods which are continuous in time. In contrast to implementations which are based on extremely high accuracy, the accuracy requirements in this case are not particularly stringent and computation power is required only at times. This is because the discrete-value and discrete-time modulation signal to be transmitted is predistorted, in one example, continuously only when the linearity of the components which are connected downstream from the predistortion unit 2 can no longer be maintained without predistortion at the instantaneously required output power level of the transmission signal. This situation occurs relatively rarely, depending on the chosen mobile radio standard.

Furthermore the described feedback loop is additionally not required all the time, since the external operating conditions change rarely or only slightly. This means that the feedback loop for the circuit 80 is activated only at specific time intervals in order to check the selected table of predistortion coefficients, and occasionally to select a new one or to calculate a new one.

Receiving devices are normally also provided, in addition to a transmitting device, in mobile communication appliances. Therefore in principle, it is possible to use the reception path of a mobile communication appliance for determination of operating variables by evaluation of a signal that has been fed back and is to be transmitted.

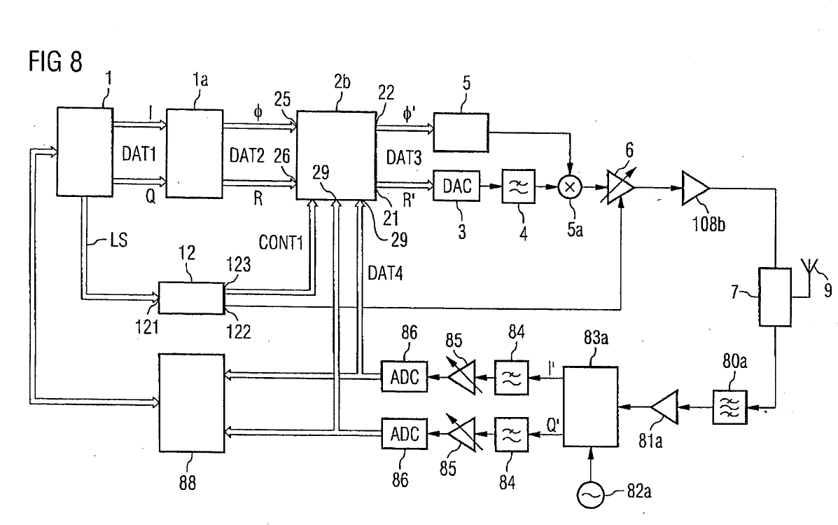

A refinement such as this is shown in FIG. 8. In this case as well, identical components have the same reference symbols. The embodiment described here is used, for example, for mobile radio methods which operate on a time-slot basis. A time-slot-based transmission method is characterized in that data is transmitted during a first time interval and data is received during a second time interval. The transmission path and the reception path are thus not active at the same time. This allows a portion of the signal to be transmitted to be fed back during the transmission process, thus allowing the necessary operating variables to be determined. Furthermore, in this embodiment, it is possible to reduce the memory and to provide only one table element with a number of pairs of predistortion coefficients, and to update this continuously during operation.

A duplexer or antenna switch is provided in order to feed back a proportion of the output signal and is connected between the output of the amplifier 108B, the antenna 9 and the input of a bandpass filter 80a. The duplexer 7 is used to pass the signal to be transmitted to the antenna 9 during transmission operation. Owing to the finite suppression in the duplexer 7, a portion of the transmission signal is passed to the input of the bandpass filter 80a. On the output side, the bandpass filter is connected to a low-noise amplifier 81a. A demodulator 83a, which is coupled to a local oscillator 82a, breaks down the signal emitted from the amplifier 81a into an in-phase component I′ and a quadrature component Q′.

The outputs of the so-called I/Q demodulator 83a are coupled via a low-pass filter 84 and a controllable amplifier 85 to the analog/digital converters 86, which convert the demodulated components I′ and Q′ to digital values, and supply them to a baseband unit 88 for further signal processing. The signal path described here, starting with the baseband filter 80 to the baseband unit 88, forms a reception path for a mobile communication appliance. In order to determine any possible distortion caused by the elements in the transmission path, the outputs of the analog/digital converters 86 are connected to the predistortion unit 2b.

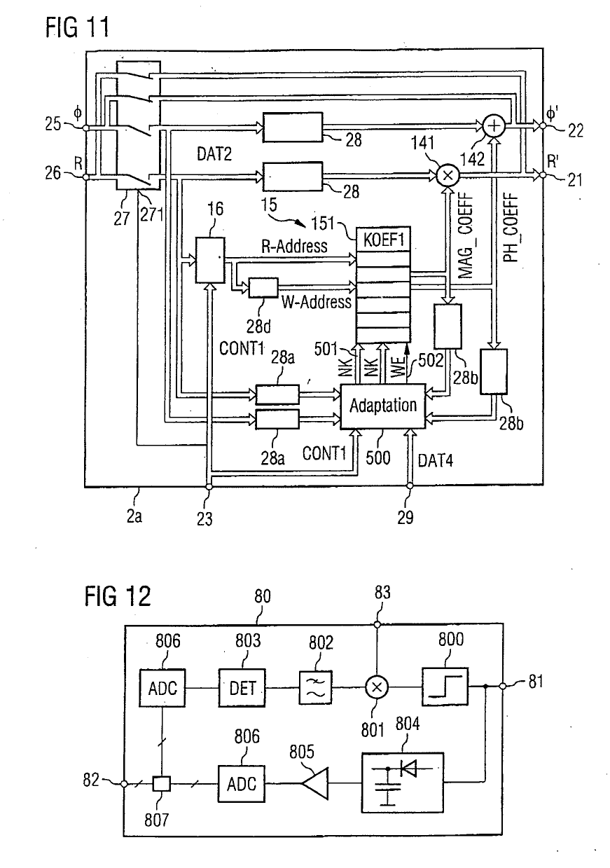

FIG. 11 shows one example embodiment of the predistortion unit 2a. Components which have the same effect and/or function are once again provided with the same reference symbols. The predistortion unit 2a is similar to the predistortion unit 2. It also has a switching apparatus 27 with signal paths connected to it. Delay elements 28 are provided in the second signal path and are used suitably to delay the first and second components until the corresponding predistortion coefficients have been taken from the memory 15. In addition, the predistortion unit 2a contains an adaptation unit 500, which is designed on the input side to receive the control signals DAT4.

The adaptation unit 500 is used to form the instantaneously used predistortion coefficients MAG_COEFF and PH_COEFF from the fed-back control signals DAT4, and to form a new pair NK of predistortion coefficients from the first and second components R and Φ. For this purpose, the adaptation unit 500 is connected to the output of the memory in order to supply the two predistortion coefficients MAG_COEFF and PH_COEFF. In the same way, the adaptation unit 500 is supplied with the first component R and with the second component Φ. Additional delay elements 28a and 28b ensure that the corresponding signals reach the adaptation unit 500 at the correct time. With suitable design, the delay elements can, of course, also be omitted.

In the present example, it is advantageous for the delay element 28a to produce a delay which corresponds to the overall delay in the forward path and backward path. This is essentially the switching elements, starting with the multiplier 141 or adder 142, the predistortion unit 2a, the other transmission path and the entire reception path. The delay in the delay elements 28b corresponds to the delay in the elements 28a minus the delay in the elements 28. Reference may be made to the document by Lee et al.: “Comparison of Different Adaption Algorithm for Adaptive Digital Predistortion Based on EDGE Standard”, IEEEMTT-S International Microwave Symposium Digest, 2001 with regard to the calculation of the new coefficient parameter NK and the design of the adaptation unit, and such reference is incorporated by reference herein in its entirety.

Once the new coefficients NK have been calculated, they are stored in the memory instead of the old coefficients. For this purpose, the adaptation unit 500 is connected via a bus 501 to the memory 15. Since the address for the correspondingly selected coefficient pair already exists and has been calculated by the address unit 16, this address can also be used to write the new predistortion coefficients NK, too. For this purpose, the address is temporarily stored in the element 28d. When a write signal WE is applied, the new predistortion coefficients NK are written to the stored address.

In this embodiment, the adaptation unit 500 according to the invention calculates new coefficient pairs and writes them where the old coefficient pairs were located. In consequence, all of the coefficient pairs are replaced by respectively newly calculated and updated pairs after a certain amount of time. This is dependent on all the amplitude values occurring at least once in the signal to be transmitted during this time period. In the same way, however, it is possible to provide an additional memory and to fill it with new, updated pairs, and then to copy the contents of the memory. Because of the adaptation and the updating of the respective coefficients within the memory, there is no need to provide a plurality of table elements with different coefficients which take account of different operating variables. The updating of the coefficients within the memory for the predistortion unit can be made dependent on various conditions. Examples of this include the age of the available coefficients, significant changes in the operating conditions such as the temperature, the power consumption or the voltage which are recorded by the sensor already provided in the transmitting device.

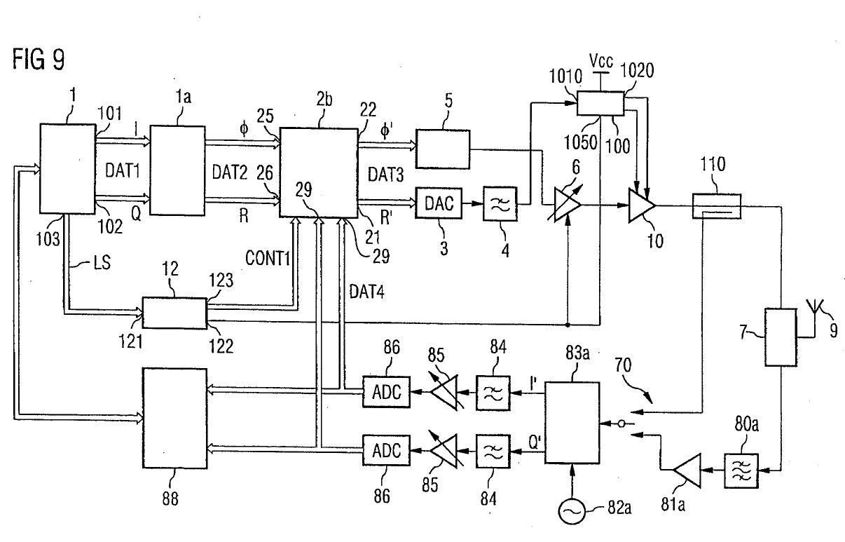

FIG. 9 shows another embodiment of a transceiver which operates with a polar transmitter.

In this embodiment the power control unit 12 is coupled via its output 122 both to the controllable amplifier 6 and to the supply voltage control circuit 100. This allows selective and more accurate adjustment of an input amplitude to the power amplifier 10. On the output side, the amplifier 10 is coupled to the antenna via a directional coupler 110. The output of the directional coupler, which outputs a portion of the signal to be transmitted, is connected to the demodulation unit 83a via a switch 70. Thus, depending on the switch position, a portion of the output signal can be fed back, and the selection and control data DAT4 can be determined from this. This data is once again supplied to the adaptation unit within the predistortion device 2b.

When the described transceiver is in a reception mode, the switch 70 is switched in such a way that the input of the demodulation unit 83 is connected to the output of the low-noise amplifier 81. During a transmission mode, the switch 70 connects the input of the modulation unit 83 to the output of the directional coupler 110. Consequently, the reception path, in particular the demodulator 83a, as far as the analog/digital converters 86, can be used both as a signal receiver and for determination of any predistortion of the transmission output signal, and thus for carrying out the adaptive predistortion process. The accuracy with which the predistortion coefficients can be determined depends on the accuracy of the demodulation by the demodulator 83a, and on the downstream elements.

On the one hand, in one example, the fed-back signal should be as large as possible in order in this way to minimize the effect of noise. On the other hand, it is desirable for the demodulator and the downstream elements themselves not to produce any additional non-linear components which lead to incorrect control signals DAT4. It may therefore be advantageous to connect an additional attenuator between the switch 70 and the directional coupler 110, in order to ensure that the input signal to the demodulator is not too large.

The embodiments described here are designed in such a way that predistortion is, in one example, carried out when there is no longer any guarantee that the downstream components will have a linear transmission response, because of the high input signal amplitude. As described, the predistortion units 2 and 2b each contain a switch which can bridge the elements that are responsible for the predistortion. This has the advantage that the elements can be switched off when predistortion is not required, in order to reduce the power consumption. In many modern mobile radio standards, high signal amplitudes are required only rarely, so that predistortion is required only at times.

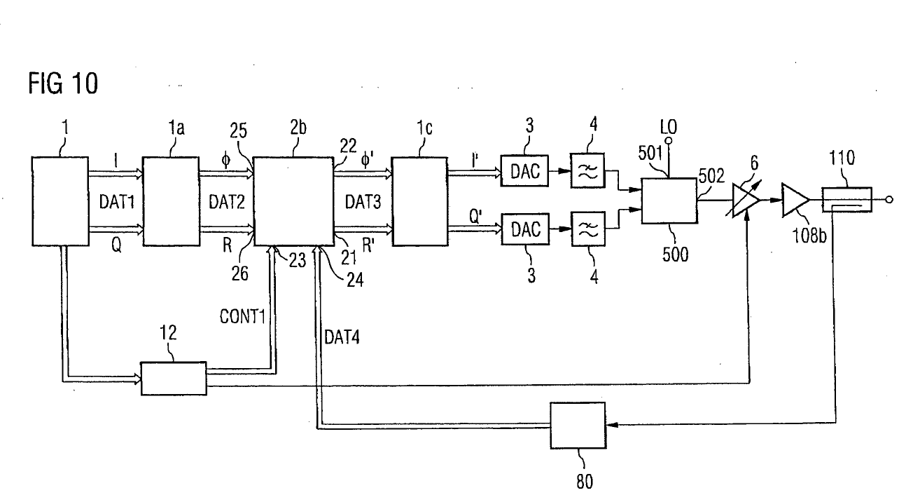

In addition to the transmitting devices described above with a polar transmitter and polar modulator, it is also possible to use an I/Q modulator for modulation of the digital modulation signal on to the carrier signal. FIG. 10 shows one possible exemplary embodiment. Components which have the same effect and/or function are provided with the same reference symbols.

In this illustration, the baseband unit is designed to emit a digital modulation signal DAT1 with the in-phase component and the quadrature component. The predistortion unit 2b is connected on the output side to a second transformation device 1c, which once again produces an in-phase component I′ and a quadrature component Q′ from the amplitude component R′ and the phase component Φ′ of the modulation signal DAT3. These are supplied via two digital/analog converters 3 to an I/Q modulator 500 which converts the two components I′ and Q′ to the carrier frequency, with the aid of a local-oscillator signal LO at the input 501. The output 502 of the I/Q modulator is connected to the input of the controllable amplifier 6.

The predistortion unit 2b is once again supplied with the control signal CONT1 and the selection signal DAT4 which it uses to produce new predistortion coefficients which it stores in its memory.

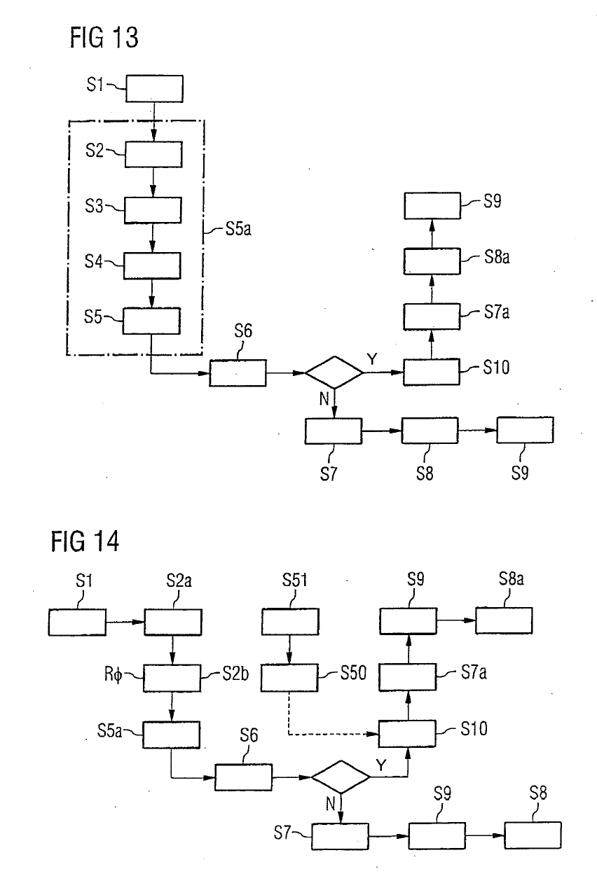

FIG. 13 shows another embodiment, an operating method according to the invention. In step S1, an amplifier circuit is provided which has a non-linear transmission response in at least one subarea of its characteristic.

In addition, a carrier signal is provided. A digital modulation signal is then produced in step S2, with a first component which forms the amplitude component and a second component which forms the phase component. In the same way, an in-phase component I and a quadrature component can be produced instead of direct provision of a phase component and an amplitude component. The amplitude information in the in-phase component and the quadrature component is obtained in one example by formation of the square of the magnitude of the in-phase component and quadrature component. The phase component of the in-phase component and quadrature component is obtained in a corresponding manner by means of a trigonometric function, for example.

In steps S3, S4 and S5, which can be combined to form an overall step S5a, a power word is produced which is derived from the first component, that is to say the amplitude component of the digital modulation signal. For this purpose, the average output signal amplitude or the output power of the modulated carrier signal which is intended to be emitted during a predetermined time interval is determined in step S3.

When data has been transmitted, modern communication standards transmit information to this receiver, in order to control the power. Mobile communication appliances evaluate this information and, furthermore, adjust the output power of their signals to be emitted for the next period. During the subsequent time interval, the average power at which the transmission signal is intended to be emitted is now determined. The maximum amplitude that occurs or the maximum value of the component which represents the amplitude component during this time interval is determined in step S4. A power word is produced from this in step S5, which contains information about the desired output power and the amplitude occurring in the input signal. A comparison process is then carried out in step S6 to determine whether the amplitude of the first component exceeds a predetermined limit value. In other words, a check is carried out in step S6 to determine whether the selected power level and the amplitude component will cause distortion during subsequent signal processing, and thus whether predistortion will be necessary.

If this is not the case, the phase of the carrier signal that is provided is modulated by the second component in step S7. The phase-modulated carrier signal is then amplitude-modulated. During this process, by way of example, the phase-modulated carrier signal is mixed with the amplitude modulation signal, which is derived from the amplitude component. As an alternative embodiment, it is possible to vary the supply voltage or the supply current to an amplifier using the amplitude component, and thus to modulate the gain of the amplifier. The phase-modulated carrier signal is supplied to the amplifier, and its amplitude is thus varied. The signal is then amplified in step S9.

If, in contrast, the comparison in step S6 shows that an amplitude exceeds a limit value which can lead to possible distortion and can thus result in data transmission errors, a pair of predistortion coefficients are selected in S10, from a large number of predistortion coefficients, on the basis of a signal derived from the power value. The selected pair is used to distort the amplitude component and phase component. The carrier signal is then modulated with the distorted phase information in step S7a. Amplitude modulation with the distorted amplitude component is carried out in step S8a.

FIG. 14 shows a slight modification of the method. Method steps which have the same function and/or the same effect are provided with the same reference symbols. After the provision of the necessary elements, in particular of the amplifier circuit, a modulation signal is provided in step S2a, which includes an in-phase component I and a quadrature component Q. This is transformed to the amplitude component R and the phase component Φ in step S2b. Processing using an amplitude component R and a phase component has the advantage that the information about the amplitude is directly available. The decision as to whether the digital modulation signal with its amplitude component R and its phase component Φ must be distorted, can thus be made easily. The power value is then produced in step S5a, and a check is carried out in step S6 to determine whether predistortion appears to be necessary.

If predistortion is not necessary, phase modulation with the undistorted phase component is carried out in step S7. The phase-modulated carrier signal is then amplified in step S9. The carrier signal that has been amplified and phase-modulated in this way now has amplitude modulation applied to it, with this amplitude modulation being formed from the undistorted amplitude component. It is particularly expedient to carry out step S9 before the amplitude modulation process when using polar transmitters in which the amplifier that is used for the amplitude modulation is generally a so-called class D or class E amplifier. These are characterized by in principle being used in an operating mode with non-linear transmission responses.

An operating mode such as this leads to high input signals still being amplified approximately linearly, while input signals with small amplitudes lead to output signals with a non-linear component. In other words, an amplifier such as this behaves in the opposite sense to an amplifier of a polar modulator, and, in particular, distorts input signals with low amplitudes. This leads to a situation in which, in step S6, a check is mainly carried out to determine whether the power control signal is below a limit value whilst step S6 according to the embodiment of the method shown in FIG. 12 checks that the limit value is exceeded.

If the comparison in step S6 of the method in FIG. 14 shows a signal distortion is being caused, a pair of. predistortion coefficients are selected in step S10. Additional parameters are used for this purpose, recording operating variables of the amplifier that is responsible for the distortion.

In step S51, these operating parameters are recorded, and a selection signal CONT2 is produced from them in step S50. This selects one table element from a large number of possible tables, this being the table element which best describes the instantaneous operating state. Each of these tables contain a plurality of pairs of predistortion coefficients. In step S10 the pair intended for use for the predistortion is now selected from the table element and the amplitude component as well as the phase component are correspondingly distorted. The distorted phase component is then used to phase-modulate a carrier signal in step S7a. In this case as well, amplification by a fixed gain factor is first of all carried out in step S9, followed by amplitude modulation with the amplitude component, which has now been distorted in step S8a.

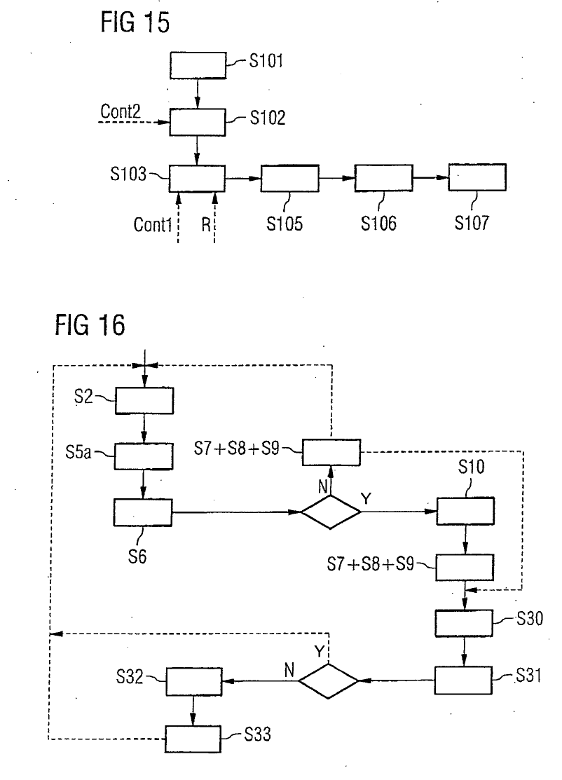

FIG. 15 shows one possible embodiment for selection of the pair of predistortion coefficients and for the subsequent distortion of the amplitude component and phase component. A vast number of pairs of predistortion coefficients are thus arranged in a plurality of table elements in step S101. In step 102, one of these table elements is selected as a function of a selection signal CONT2 that is supplied. The selection signal CONT2 characterizes external operating parameters of the components which are causing distortion.

The respective table elements provide the pairs of predistortion coefficients which are most suitable in the respective operating conditions to compensate for the predistortion. In other words, each individual table element describes the circuits with a non-linear transmission response in an operating state which is characterized by a set of significant influencing variables. Apart from the selected table element, the suitable pair of predistortion coefficients is selected in step S103 with the aid of the amplitude component R and of the control signal derived from the power value.

The amplitude component is multiplied by one of the two coefficients of the predistortion coefficient pair in step S105. In the same way, a phase component at the same time has the phase coefficient added to it in step S106. In this case, the time period which is required for selection of the appropriate predistortion coefficients is taken into account. The predistorted components are emitted in step S107.

The capability for updating by recalculation of the individual pairs of predistortion coefficients and subsequent storage in the memory makes it possible to reduce the memory size and, possibly, even to dispense with additional sensors for recording the individual operating variables of the components which are responsible for distortion.

FIG. 16 shows an exemplary embodiment of the method in which new predistortion coefficients are calculated. Once again, the same reference symbols denote the same method steps. As indicated here, the method is repeated after step S9, by producing a new modulation signal. It is obvious that the method is carried out continuously during a time period.

When the comparison in step S6 shows the need for distortion, the pair of predistortion coefficients are determined in step S10. The amplitude component R and the phase component Φ of the digital modulation signal are distorted using the appropriate coefficient elements. The carrier signal is then modulated with the distorted phase component, and its amplitude is varied using the distorted amplitude component.

This embodiment of the method provides for the characteristic variables for characterization of the operating state of the at least one amplifying circuit to be obtained by demodulation of the modulated carrier signal. For this purpose, a portion of the output signal output in step S30, is fed back and is demodulated. The demodulation of the fed-back signal results in an in-phase component and a quadrature component, which form a baseband signal. The demodulated baseband signal is compared with the original modulation signal in step S31. This can be done, for example, on a component basis in the baseband unit. However, it is likewise possible to determine the amplitude component as well as the phase component from the in-phase component and the quadrature component of the demodulated baseband signal. This amplitude component and phase component can then be compared directly with the components of the undistorted modulation signal. If the coefficients used for distortion are sufficiently suitable to compensate for the distortion caused by the amplification, the comparison of the demodulated signal and of the original modulation signal in step S31 would have to show a high degree of match. If this is the case, it is possible to jump back to step S2 again.

Otherwise, a new pair of predistortion coefficients must be calculated in step S32. For this purpose, the original first and second components R and Φ, the demodulated baseband signal with its two components and the coefficients used for the distortion process are acquired for this purpose. The new pair is then written in step S33 to the address of the predistortion coefficients being used. The pair of predistortion coefficients that are used is thus replaced by a new updated pair, which takes account of the new operating conditions.

This refinement of the method has the advantage that characteristic variables for characterization by means of the demodulation can nevertheless still be recorded for modulation with the undistorted first and second components. At the same time, this procedure allows considerably fewer predistortion coefficients to be calculated and to have to be stored in the memory. The recording of the characteristic variables by means of demodulation can also be made dependent on the type of modulation used, on the mobile radio standard being used, and on external parameters. In addition to recording of a characteristic variable by demodulation, it is likewise possible to determine other characteristic variables, for example the temperature, the power consumption and impedance, or a reflection coefficient, and to use these to produce and calculate a new pair of predistortion coefficients. Step S30 is accordingly not restricted to demodulation of an output portion of the signal to be transmitted.

The disclosed method is particularly suitable for use in mobile communication systems. In this case, the individual steps can be used without any additional implementation complexity in already existing communication appliances. Particularly in modern communication appliances, in which the transmitter and receiver are essentially provided in a semiconductor body, parts of the reception path can be used for the determination and for the recording of individual characteristic variables of the transmission path. There is therefore no need for any additional switching elements.

The power consumption resulting from the predistortion by a predistortion unit is more than compensated for by the power saving in the downstream components, in particular in the power amplifiers. Overall, the activation of predistortion at times and selectively, makes it possible to achieve a power saving in the overall transmitting device thus in fact considerably lengthening the operating time of mobile communication appliances and being operated from rechargeable batteries. In this case, the various aspects of the exemplary embodiments described can be combined without departing from the essence of the invention.

While the invention has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

1. A method for signal processing, comprising:
providing of at least one amplifier circuit characterized by at least one characteristic variable during operation;
providing a discrete-value and discrete-time modulation signal comprising a first component and a second component, and providing a carrier signal with an amplitude and a phase;
providing a plurality of selectable pairs of predistortion coefficients;
producing a power word that is a function of the first component of the modulation signal;
comparing the power word with a reference value and producing a first result or a second result in response thereto;
selecting a pair of predistortion coefficients from the plurality of selectable pairs as a function of the first component and a control word derived from the power word;
distorting the first component with a first coefficient of the selected pair of predistortion coefficients and distorting the second component with a second coefficient of the selected pair of predistortion coefficients when the comparison has produced the first result;
modulating the phase of the carrier signal with the distorted second component of the modulation signal when the comparison has produced the first result, or modulating the phase of the carrier signal with the second component of the modulation signal when the comparison has produced the second result;
modulating the amplitude of the phase-modulated carrier signal as a function of the distorted first component of the modulation signal when the comparison has produced the first result, or modulating the amplitude of the phase-modulated carrier signal with the first component of the modulation signal when the comparison has produced the second result; and
amplifying the modulated carrier signal by the at least one amplifier circuit.

2. The method of claim 1, further comprising:
recording the at least one characteristic variable of the at least one amplifier circuit, and
producing a selection word based on the recorded characteristic variable;
wherein the selected pair of distortion coefficients are selected as a function of the first component, the control word and the selection word.

3. The method of claim 2,
wherein recording the at least one characteristic variable comprises:
determining a temperature of the at least one amplifier circuit;
determining a current consumption of the at least one amplifier circuit;
determining a supply voltage of the at least one amplifier circuit;
determining an impedance or an impedance change of the at least one amplifier circuit;
determining a reflection coefficient at a signal output of the at least one amplifier circuit.

4. The method of claim 2,
wherein recording the at least one characteristic variable comprises:
outputting a signal element from the amplified carrier signal emitted from the at least one amplifier;
determining an envelope of the signal element;
determining a phase difference between the signal element and the phase-modulated carrier signal; and
producing the selection word based on the determined envelope and the phase difference.

5. The method of claim 2,
wherein recording the at least one characteristic variable comprises:
outputting a signal element from the amplified carrier signal emitted from the at least one amplifier;
converting a frequency of the signal element using a local-oscillator signal;
decomposing the frequency-converted signal element into a third component and a fourth component; and
producing the selection word based on the third component and the fourth component.

6. The method of claim 1,
wherein providing the modulation signal comprises:
providing an in-phase component and a quadrature component associated with transmission data;
producing the first component by forming a square of the magnitude from the in-phase component and the quadrature component; and
producing the second component from the in-phase component and the quadrature component.

7. The method of claim 1,
wherein producing the power word comprises:
determining a carrier signal power level to be emitted during a time interval;
determining a value of a maximum of the first component during that time interval; and
producing the power word based on the determined power to be emitted and the maximum value of the first component.

8. The method of claim 1,
wherein producing the first or second result comprises:
producing the first result when the comparison shows that a value of the first component exceeds the reference value, and producing the second result when the value of the first component does not exceed the reference value; or
producing the first result when the comparison shows that a value of the first component does not exceed the reference value, and producing the second result when the value of the first component exceeds the reference value.

9. The method of claim 1,
wherein selecting the pair of predistortion coefficients comprises:
arranging the plurality of pairs of predistortion coefficients, with an address being allocated to each pair;
generating an address from the first component and from the control word comprising multiplication or scaling of the first component by a factor which is derived from the control word; and
determining the pair of predistortion coefficients allocated to the generated address.

10. The method of claim 9,
wherein the arrangement of the predistortion coefficients comprises:
arranging the plurality of pairs of predistortion coefficients in a first table element and in at least one second table element with an address being allocated to each pair of predistortion coefficients; and
selecting one table element from the first and the at least one second table element as a function of the selection word.

11. The method of claim 9,
wherein selection of a pair of predistortion coefficients comprises:
forming a new pair of predistortion coefficients from the first and second components, the control word, the selection word, and the determined pair of predistortion coefficients; and
replacing the determined pair of predistortion coefficients by the newly formed pair of predistortion coefficients.

12. The method of claim 10,
wherein selecting of a table element and selecting the predistortion coefficient comprises:
forming a first address part by evaluation of the selection word;
forming a second address part by scaling the first component by a factor derived from the control word;
combining the first and the second address part to form an address; and
determining the predistortion coefficients associated with the address that has been formed.

13. A transmitting device with digital predistortion, comprising:
a signal processing device configured to produce and emit a discrete-value and a discrete-time modulation signal with a first component and a second component, and further configured to emit a power control signal which is derived from the first component to a control output;
a predistortion device, comprising:
a first signal path configured to pass the modulation signal to an output thereof;
a second signal path including switching elements for distortion of the modulation signal as a function of a signal present at a control input and as a function of the first component;
wherein the predistortion device is configured to activate the first or the second signal path as a function of the signal at the control input and output a selectively predistorted modulation signal;
a modulation unit configured to modulate a phase of a carrier signal with a portion of the selectively predistorted modulation signal;
at least one variable gain amplifier circuit whose input is coupled to an output of the modulation unit;
a power control unit connected to a control output of the signal processing device, with a first output connected to a control input of the predistortion device, and a second output coupled to the at least one amplifier circuit for gain adjustment, the power control unit configured to emit a control signal for predistortion at the first output, and a gain adjustment signal at the second output based on the power control signal applied to its input.

14. The transmitting device of claim 13, further comprising means for recording at least one characteristic variable which describes an operating state of the amplifier circuit and produce and emit a control word to a selection input of the predistortion device, and
wherein the second signal path of the predistortion device is configured to produce distortion as a function of the selection word of the modulation signals.

15. The transmission device of claim 14,
wherein the means are configured to record at least one of the following characteristic variables:
a temperature of the amplifier circuit;
a current consumption of the amplifier circuit;
a supply voltage of the amplifier circuit;
an impedance or an impedance change of the amplifier circuit;
a reflection coefficient at a signal output of the amplifier circuit; and
a phase and/or an amplitude of an output signal from the amplifier circuit.

16. The transmission device of claim 14,
wherein the recording means comprises:
a directional coupler coupled to an output of the amplifier circuit and configured to emit a feedback signal component associated with an output signal at the output;
an envelope curve detector, connected to the directional coupler and configured to detect and emit an amplitude component of the output signal to the selection input of the predistortion device; and
a phase detector with a first input coupled to the directional coupler and a second input coupled to an output of the modulation unit, wherein the phase detector is configured to emit a difference signal based on a difference between the feedback signal and a phase modulated carrier signal output from the modulation unit and provide the difference signal to a selection input of the predistortion device.

17. The transmitting device of claim 13,
wherein the predistortion device comprises a memory comprising a plurality of addressable pairs of predistortion coefficients stored therein, and an address unit connected to the memory, and configured to produce an address of a pair of predistortion coefficients from the first component and the signal which is applied to the control input of the predistortion device.

18. The transmitting device of claim 17,
wherein the address unit comprises a scalar multiplication unit configured to multiply the first component by a factor which is derived from the signal applied to the control input of the predistortion unit.

19. The transmitting device of claim 17,
wherein the predistortion unit comprises a calculation unit configured:
to calculate a new pair of predistortion coefficients from the first component, the selection word, and a determined pair of predistortion coefficients, and further configured
to store the new pair in the memory at the produced address.

20. The transmitting device of claim 13, further comprising:
a scalar multiplication unit arranged in the second signal path of the predistortion device and configured to multiply the first component by a first coefficient element of the pair of predistortion coefficients; and
an addition unit arranged in the second signal path of the predistortion device and configured to add the second component to a second coefficient element of the pair of predistortion coefficients.

21. The transmitting device of claim 13, wherein the at least one amplifier circuit comprises an input for gain modulation coupled to an output of the predistortion device.

22. The transmitting device of claim 13, further comprising:
a supply voltage control circuit coupled to the predistortion device and configured to emit a voltage dependent on an input control signal to an output which is connected to a voltage supply input of the at least one amplifier circuit.
